(19) United States
(12) Patent Application Publication
(10) Pub. No.: US 2011/0203632 A1
(43) Pub. Date: Aug. 25, 2011

(54) PHOTOVOLTAIC DEVICES USING SEMICONDUCTING NANOTUBE LAYERS

(76) Inventors: RAHUL SEN, LEXINGTON, MA (US); SUCHIT SHAH, BOSTON, MA (US); HAO-YU LIN, WOBURN, MA (US); THOMAS RUECKES, ROCKPORT, MA (US)

(21) Appl. No.: 12/709,923

(22) Filed: Feb. 22, 2010

(51) Int. Cl. H01L 31/042; H01L 31/00; H01L 31/18

(52) U.S. Cl. 136/244; 136/261; 136/255; 438/92; 257/E31.002; 977/742

(57) ABSTRACT

Photovoltaic (PV) devices employing layers of semiconducting carbon nanotubes as light absorption elements are disclosed. In one aspect a layer of p-type carbon nanotubes and a layer of n-type carbon nanotubes are used to form a p-n junction PV device. In another aspect a mixed layer of p-type and n-type carbon nanotubes are used to form a bulk hetero-junction PV device. In another aspect a metal such as a low work function metal electrode is formed adjacent to a layer of semiconducting nanotubes to form a Schottky barrier PV device. In another aspect various material deposition techniques well suited to working with nanotube layers are employed to realize a practical metal-insulator-semiconductor (MIS) PV device. In another aspect layers of metallic nanotubes are used to provide flexible electrode elements for PV devices. In another aspect layers of metallic nanotubes are used to provide transparent electrode elements for PV devices.

### TECHNICAL FIELD

The present disclosure relates to photovoltaic device and solar cells, and more particularly to the use of semiconducting nanotube layers within such devices and cells.

### BACKGROUND

Any discussion of the related art throughout this specification should in no way be considered as an admission that such art is widely known or forms part of the common general knowledge in the field.

The most commonly known photovoltaic (PV) devices are formed by placing a layer of n-type crystalline silicon into contact with a layer of p-type crystalline silicon. In practice, this is typically accomplished by diffusing an n-type dopant (such as, but not limited to, phosphorus into one side of a silicon layer previously doped with a p-type dopant (such as, but not limited to, boron) or vice versa. Free electrons within the n-type silicon layer flow into the p-type layer—which possesses a deficiency of free electrons or, taken another way, possesses a plurality of excess holes—until the Fermi levels of the two layers are substantially equal. In this way, a p-n junction—a voltage barrier introduced by the initial electron diffusion—is formed along the interface of the two silicon layers. Within silicon, this voltage barrier is typically around 0.6 to 0.7 Volts.

Within such a PV device, the p-type silicon layer becomes the light absorption material. When a photon impacts the p-type silicon layer—as would be the case if the PV device was placed in direct sunlight—the photon may be absorbed into the layer. A number of factors determine the likelihood of a photon being absorbed by the silicon layer, including the thickness of the p-type silicon layer (the more silicon material a photon travels through, the more likely it will be absorbed) and the energy of the photon itself. Photons with energy levels approximately equal to the band gap energy of crystalline silicon (about 1.1 eV) and higher—or in the case of non-silicon based PV devices, the band gap energy of the material within the light absorption layer—can be absorbed. Photons with energy levels below the band gap energy typically pass directly through the silicon layer without being absorbed. Photons with energy levels significantly higher than the band gap energy may be absorbed, but the excess energy will be converted to heat (and not electricity).

When a photon is absorbed into the p-type silicon layer, the photon's energy is transferred to a valance band electron within the silicon layer. This energy will usually be enough to excite the electron into the conduction band, allowing the electron to move freely through the silicon material. This process is known by those skilled in the art as photoexcitation. When a load is placed across the PV device, these freed electrons will tend to flow from the p-type crystalline silicon layer into the n-type crystalline layer and also through the load under the influence of the voltage generated at the p-n junction. In this way, the energy of the photons striking the PV device (solar energy) is converted into electricity which can either be stored within or used by an attached load.

One significant limitation of crystalline silicon based PV devices is the thickness of the p-type silicon layer. As crystalline silicon is a relatively poor light absorber, the p-type layer within such PV devices usually needs to be relatively thick (in some cases on the order of hundreds of microns thick) in order to realize a PV device with reasonable efficiency. This can significantly increase the cost of a PV device as well as limit the efficiency (freed electrons will have a tendency to fall back into holes left by other electrons when traveling through a thick p-type layer).

Thin-film PV devices attempt to overcome this limitation through the use of less expensive materials which are strong light absorbers and can be disposed over large areas (in some cases on the order of one meter or more). Materials well suited to thin-film PV devices include amorphous silicon, cadmium telluride (CdTe), and copper indium (gallium) diselenide. A thin-film PV device is formed by applying one or more thin layers of a photovoltaic material over a substrate (such as glass) which has been coated with a transparent or partially transparent conducting layer. Depending on the material used, these thin layers can range in thickness from tens of nanometers to tens of microns and are typically formed through chemical vapor deposition (CVD).

Although typically less efficient than traditional crystalline silicon PV devices, lower material cost and ease of fabrication in large scale devices make thin-film PV devices viable solutions within certain applications.

Within all of the previously described types of PV devices, conductive elements are necessary to form electrodes along the top and bottom of the PV device such that a load can be placed across the PV device to either store or use the electrical energy generated within the PV device. The electrode placed over the light absorption layer (usually simply referred to as the “top electrode” by those skilled in the art) must allow photons to pass through into the light absorption layer while maintaining good electrical contact with the PV device such as to maximize the conductivity between the electron donor layer and an attached load. Typically, these functions are both served by selecting a transparent conductive material such as ITO for the top electrode.

U.S. Pat. Nos. 6,835,591, 7,335,395, 7,259,410, 6,924,538, and 7,375,369 disclose approaches for making nanotube films and articles, e.g., nanotube fabrics such as carbon nanotube fabrics and articles made therefrom. The entire contents of each of these patents is incorporated herein by reference.

U.S. Patent Application Publication Nos. 20080299307, 20050058797, 20080012047, 20060183278, 20080251723, and 20080170429 also disclose approaches for making nanotube films and articles, e.g., nanotube fabrics such as carbon nanotube fabrics and articles made therefrom. The entire contents of each of these published patent applications is incorporated herein by reference.

Copending U.S. patent application Ser. No. 12/274,033 filed Nov. 19, 2008, discloses approaches for making nanotube films, e.g., nanotube fabrics, that include nanoscopic particles, and copending U.S. patent application. Ser. No. 12/553,695 filed Jul. 31, 2009, discloses approaches for making nanotube films, e.g., nanotube fabrics, having anisotropy. The entire contents of each of these patent applications is incorporated herein by reference.

The present inventors have identified a need for photovoltaic devices that are less costly and easier to fabricate that conventional silicon-based PV devices. The present inventors have also recognized a desire for PV devices which are physically flexible so as to allow a PV device to conform to a plurality of underlying support structures including, but not limited to, flexible support structures.

### SUMMARY OF THE DISCLOSURE

The present disclosure relates to photovoltaic (PV) devices which employ layers of semiconducting carbon nanotubes as light absorption materials.

According to one example, a photovoltaic device comprises a first electrode element, a second electrode element; a layer of semiconducting elements disposed between said first and second electrode elements, said layer of semiconducting elements comprising a fabric of semiconducting carbon nanotubes having a first conductivity type, said layer of semiconducting elements having a first side and a second side, and at least one charge-separating junction formed at (e.g., on a surface thereof or within) said layer of semiconducting elements. The first side of said layer of semiconducting elements is electrically coupled to said first electrode element, and the second side of said layer of semiconducting elements is electrically coupled to said second electrode element.

According to another example, a photovoltaic power generating system comprises multiple photovoltaic devices electrically coupled together, and an electrical inverter electrically coupled to an output section of said multiple photovoltaic devices, wherein said inverter receives a DC electric current from said output section and converts the DC electric current to an AC electric current. Each of the multiple photovoltaic devices comprises a first electrode element, a second electrode element; a layer of semiconducting elements disposed between said first and second electrode elements, said layer of semiconducting elements comprising a fabric of semiconducting carbon nanotubes having a first conductivity type, said layer of semiconducting elements having a first side and a second side, and at least one charge-separating junction formed at said layer of semiconducting elements. The first side of said layer of semiconducting elements is electrically coupled to said first electrode element, and the second side of said layer of semiconducting elements is electrically coupled to said second electrode element.

According to another example, a method of fabricating photovoltaic device comprises forming a layer of semiconducting elements on a first electrode element, said layer of semiconducting elements comprising a plurality of carbon nanotubes of a first conductivity type, said layer of semiconducting elements having a first side and a second side, said first side of the layer of semiconducting elements disposed at a surface of said first electrode element, said first side of said layer of semiconducting elements being electrically coupled to said first electrode element. The method also comprises forming a second electrode element at said second side of said layer of semiconducting elements, said second side of said layer of semiconducting elements being electrically coupled to said second electrode element, and forming at least one charge-separating junction at said layer of semiconducting elements.

In particular, for example, the present disclosure describes a photovoltaic device comprising a first electrode element, a second electrode element, a first layer of semiconducting elements, and a second layer of semiconducting elements. The first layer of semiconducting elements, which includes a first side and a second side, comprises a plurality of n-type carbon nanotubes. The second layer of semiconducting elements, which also includes a first side and a second side, comprises a plurality of p-type carbon nanotubes. Within this photovoltaic device the first side of the first layer of semiconducting elements is electrically coupled to the first electrode element, and the first side of the second layer of semiconducting elements is electrically coupled to the second electrode element. Further, the second side of the first layer of semiconducting elements is electrically coupled to the second side of the second layer of semiconducting elements, forming a p-n junction interface between the first layer and the second layer.

The present disclosure also describes a photovoltaic device comprising a first electrode element, a second electrode element, and a layer of semiconducting elements. The layer of semiconducting elements, which includes a first side and a second side, comprises a first plurality of n-type carbon nanotubes and a second plurality of p-type carbon nanotubes. Within this photovoltaic device the first side of the layer of semiconducting elements is electrically coupled to said first electrode element and the second side of the layer of semiconducting elements is electrically coupled to the second electrode element.

The present disclosure also describes a photovoltaic device comprising a first electrode element, a second electrode element, and a layer of semiconducting elements. The second electrode element is comprised of a metal, e.g., a low work function metal, and the layer of semiconducting elements, which includes a first side and a second side, comprises a plurality of semiconducting carbon nanotubes. Within this photovoltaic device the first side of the layer of semiconducting elements is electrically coupled to the first electrode element, and the second side of the layer of semiconducting elements is electrically coupled to the second electrode element, forming a Schottky barrier between the layer of semiconducting elements and the second electrode element.

The present disclosure also describes a photovoltaic device comprising a first electrode element, a second electrode element, a layer of semiconducting elements, and a layer of insulating material. The second electrode element is comprised of a metal, e.g., a low work function metal. The layer of semiconducting elements, which includes a first side and a second side, comprises a plurality of semiconducting carbon nanotubes. The layer of insulating material includes a first side and a second side. Within this photovoltaic device the first side of the layer of semiconducting elements is electrically coupled to the first electrode element, and the first side of the layer of insulating material is electrically coupled to the second electrode element. The second side of the layer of semiconducting elements is electrically coupled to the second side of said layer of insulating material. Further, at least a portion of the layer of insulating material is positioned within a Schottky barrier formed between the layer of semiconducting elements and the second electrode element.

The present disclosure also describes a photovoltaic device comprising a first electrode element, a second electrode element, and a composite active layer. The composite active layer, which includes a first side and a second side, comprises a first plurality of semiconducting nanotube elements and a second plurality of silicon particles. Within this photovoltaic device the first side of the composite active layer is electrically coupled to the first electrode element, and the second side of the composite active layer is electrically coupled to the second electrode element.

Within one aspect of the present disclosure a layer of p-type semiconducting nanotubes are disposed adjacent to a layer of n-type semiconducting nanotubes to realize a p-n junction photovoltaic device.

Within another aspect of the present disclosure a mixed layer of p-type and n-type semiconducting nanotubes is formed to realize a bulk hetero junction photovoltaic device.

Within another aspect of the present disclosure a layer of semiconducting nanotubes is disposed adjacent to a metal, e.g., a low work function metal electrode to realize a Schottky barrier photovoltaic device.

Within another aspect of the present disclosure a layer of insulating material is disposed between a layer of semiconducting nanotubes and a layer of metal, e.g., a low work function metal to realize a metal-insulator-semiconductor (MIS) photovoltaic device.

Within another aspect of the present disclosure photosensitive particles are used within a layer of semiconducting nanotubes to improve the light absorption rate of the layer.

Within another aspect of the present disclosure a layer of metallic nanotubes are used to provide a flexible electrode element for a photovoltaic device.

Within another aspect of the present disclosure a layer of metallic nanotubes are used to provide a substantially transparent electrode element for a photovoltaic device.

Other features and advantages of the present disclosure will become apparent from the following description of the disclosure which is provided below in relation to the accompanying drawings.

### BRIEF DESCRIPTION OF THE DRAWINGS

FIG. 1A is a diagram illustrating an exemplary nanotube based p-n junction photovoltaic (PV) device which includes a light absorption layer comprising a plurality of p-type nanotube elements;

FIG. 1B is a diagram illustrating an exemplary method of fabricating a PV device;

FIG. 2 is a diagram illustrating an exemplary nanotube based p-n junction photovoltaic (PV) device which includes a light absorption layer comprising a plurality of p-type nanotube elements and a plurality of photosensitive particles;

FIG. 3 is a diagram illustrating an exemplary nanotube based bulk hetero junction photovoltaic (PV) device which includes a light absorption layer comprising a plurality of p-type nanotube elements and a plurality n-type nanotube elements;

FIG. 4 is a diagram illustrating an exemplary nanotube based bulk hetero junction photovoltaic (PV) device which includes a light absorption layer comprising a plurality of p-type nanotube elements, a plurality of n-type nanotube elements, and a plurality of photosensitive particles;

FIG. 5 is a diagram illustrating an exemplary nanotube based Schottky barrier photovoltaic (PV) device which includes a light absorption layer comprising a plurality of semiconducting nanotube elements;

FIG. 6 is a diagram illustrating an exemplary nanotube based Schottky barrier photovoltaic (PV) device which includes a light absorption layer comprising a plurality of semiconducting nanotube elements and a plurality of photosensitive particles;

FIG. 7 is a diagram illustrating an exemplary nanotube based metal-insulator-semiconductor (MIS) photovoltaic (PV) device which includes a light absorption layer comprising a plurality of semiconducting nanotube elements;

FIG. 8 is a diagram illustrating an exemplary nanotube based metal-insulator-semiconductor (MIS) photovoltaic (PV) device which includes a light absorption layer comprising a plurality of semiconducting nanotube elements and wherein the insulating layer has been formed using the nanostructure of the semiconducting nanotube layer as a template;

FIG. 9 is a diagram illustrating an exemplary nanotube based metal-insulator-semiconductor (MIS) photovoltaic (PV) device which includes a light absorption layer comprising a plurality of semiconducting nanotube elements and wherein the insulating layer has been formed using an atomic layer deposition (ALD) process.

FIG. 10 is a diagram illustrating an exemplary nanotube based metal-insulator-semiconductor (MIS) photovoltaic (PV) device which includes a light absorption layer comprising a plurality of semiconducting nanotube elements and wherein the insulating layer has been formed by depositing a layer of nonconductive nanotube elements;

FIG. 11 is a diagram illustrating an exemplary nanotube based metal-insulator-semiconductor (MIS) photovoltaic (PV) device which includes a light absorption layer comprising a plurality of semiconducting nanotube elements and wherein the insulating layer has been formed by depositing a layer of nanotube elements coated with a plurality of nonconductive nanoparticles;

FIG. 12 is a diagram illustrating an exemplary nanotube based bulk hetero-junction photovoltaic (PV) device which includes a composite active layer comprising a first plurality of semiconducting nanotube elements and a second plurality of doped silicon particles;

FIG. 13 is a perspective drawing illustrating an exemplary flexible p-n junction photovoltaic (PV) device which includes flexible conductive nanotube layers and transparent conductive nanotube layers as the electrode elements; and

FIG. 14 is a block diagram illustrating an exemplary PV power generating system.

### DETAILED DESCRIPTION

The present disclosure teaches a plurality of photovoltaic (PV) devices which use layers of semiconducting carbon nanotubes as the light absorption layer.

In some embodiments of the present disclosure a p-n junction PV device is realized by forming a layer of p-type semiconducting carbon nanotubes adjacent to a layer of n-type semiconducting carbon nanotubes, creating a p-n junction across the interface of the two layers. Within such embodiments, the p-type carbon nanotube layer acts as a light absorption material, releasing valance electrons into the conduction band of the nanotube structures when photons are absorbed. In some aspects of these embodiments, these p-type carbon nanotube layers include photosensitive particles such as, but not limited to, photosensitive dyes such as ruthenium-polypyridine and quantum dots made from III-V compounds such as GaAs, GaSb, and InP or II-VI compounds such as CdS, CdSe, ZnS, and ZnSe. Such nanoparticles can be dispersed in the nanotube layers (e.g., by spin coating or spray coating a mixture carbon nanotubes and photosensitive particles onto an electrode) to increase the rate of photon absorption.

In other embodiments of the present disclosure a bulk hetero junction PV device is realized by forming a single mixed layer of n-type and p-type semiconducting carbon nanotubes. Within such embodiments, p-type and n-type carbon nanotube elements are mixed together on a nanometer scale allowing for carrier diffusion of photoexcited electrons through the nanotube layer. In some aspects of these embodiments, this mixed p-type and n-type carbon nanotube layer is infused with photosensitive particles (such as, but not limited to, photosensitive dyes and quantum dots as described above) to increase the rate of photon absorption.

In other embodiments of the present disclosure a PV device is realized by forming a layer of p-type semiconducting carbon nanotubes adjacent to a metal, e.g., a low work function metal layer (such as, but not limited to, calcium, potassium, manganese, silver, aluminum, zinc, titanium, and iron). A Schottky barrier is created along the interface between the p-type nanotube layer and the metal layer, allowing the transport of minority carriers across the interface. Within such embodiments, the p-type carbon nanotube layer acts as a light absorption material, releasing valance electrons into the conduction band of the nanotube structures when photons are absorbed. In some aspects of these embodiments, these p-type carbon nanotube layers include photosensitive particles (such as, but not limited to, photosensitive dyes and quantum dots as described above) to increase the rate of photon absorption.

In other embodiments of the present disclosure a metal-insulator-semiconductor (MIS) PV device is constructed by forming a thin barrier layer of insulating material between a layer of p-type carbon nanotubes and a metal, e.g., a low work function metal layer (such as, but not limited to, calcium, potassium, manganese, silver, aluminum, zinc, titanium, and iron). Within such embodiments, the insulating barrier layer enhances the transport of photo generated charge carriers (photoexcited electrons within the p-type nanotube layer) through the PV device.

Within the embodiments of the present disclosure, PV devices comprise one or more nanotube layers which are formed over or adjacent to other material layers. The formation of such nanotube layers is taught in several of the incorporated references. For example, U.S. Pat. No. 7,335,395 to Ward et al., incorporated herein by reference in its entirety, teaches a plurality of methods for forming nanotube layers and films on a substrate element using preformed nanotubes. The methods include, but are not limited to, spin coating (wherein a solution of nanotubes is deposited on a substrate which is then spun to evenly distribute the solution across the surface of the substrate), spray coating (wherein a plurality of nanotube are suspended within an aerosol solution which is then disbursed over a substrate) and roll-to-roll coating (or roll coating, for brevity) such as Gravure coating (wherein an engraved roller with a surface spinning in a coating bath picks up the coating solution in the engraved dots or lines of the roller, and where the coating is then deposited onto a substrate as it passes between the engraved roller and a pressure roller). Further, U.S. Pat. No. 7,375,369 to Sen et al., incorporated herein by reference in its entirety, teaches solvents that are well suited for suspending nanotubes and for forming a nanotube layer over a substrate element via a spin coating process. For example, such solvents include but are not limited to ethyl lactate, dimethyl sulfoxide (DMSO), monomethyl ether, 4-methyl-2 pentanone, N-methylpyrrolidone (NMP), t-butyl alcohol, methoxy propanol, propylene glycol, ethylene glycol, gamma butyrolactone, benzyl benzoate, salicyladehyde, tetramethyl ammonium hydroxide and esters of alpha-hydroxy carboxylic acids. Such solvents can disperse the nanotubes to form a stable composition without the addition of surfactants or other surface-active agents.

Depending on their physical structure, individual carbon nanotubes can be highly conductive or semiconducting (such that they behave like silicon). The conductivity of an individual carbon nanotube is determined by the orientation of the hexagonal rings around the wall of the nanotube. This orientation is referred to as the chirality (or twist) of the nanotube by those skilled in the art and can be quantified as the angle between the hexagonal pattern of the individual carbon rings making up the wall of the nanotube and the axis of the nanotube itself. Within a typical distribution of fabricated carbon nanotubes, for example, roughly one third will be conducting (often simply referred to as metallic nanotubes) and two thirds will be semiconducting.

In some applications it is desirable to form a layer of carbon nanotube elements that includes substantially only semiconducting carbon nanotubes. For example, U.S. Published Patent. Application No. 20060183278 to Bertin et al., incorporated herein by reference in its entirety, teaches the construction of a FET device which includes a layer of semiconducting carbon nanotubes as the channel element. U.S. 20060183278 teaches a method of “burning off” the metallic nanotubes within a deposited nanotube layer during the fabrication of a FET device. A nanotube layer is deposited over a substrate and thermally isolated from the underlying substrate (in at least one embodiment, by forming a gap within the substrate beneath the nanotube layer). An electrical current is then passed through the nanotube layer. With no structure available to dissipate the heat generated, the thermally isolated metallic nanotubes within the nanotube layer are burnt off, leaving behind a nanotube layer comprised of substantially only semiconducting nanotubes.

Further, as the need for semiconducting carbon nanotubes increases, additional techniques are being developed within the industry to manufacture supplies of semiconducting only carbon nanotubes. Such techniques include methods to sort metallic carbon nanotubes from semiconducting nanotubes, as well as methods for fabricating carbon nanotubes such that the percentage of metallic nanotubes produced is much smaller than the percentage of semiconducting nanotubes produced. As these techniques continue to develop, supplies of semiconducting only carbon nanotubes are expected to become more readily available. Current separation techniques of metallic SWNTs and MWNTs impurities from s-SWNT result in s-SWNT concentrations in the range of greater than 80%, but less than 100%, with some metallic CNTs remaining. Examples of separation techniques in use are metallic burnoff, dielectrophoresis (e.g., AC dielectrophoresis and agarose gel electrophoresis), amine extraction, polymer wrapping, selective oxidation, CNT functionalization, and density-gradient ultracentrifugation.

Typically, semiconducting carbon nanotubes are formed as p-type semiconducting elements. However semiconducting carbon nanotubes can be converted to n-type semiconducting elements through a plurality of methods well known to those skilled in the art. These include, but are not limited to, high temperature thermal anneal processes and doping a layer of p-type carbon nanotubes with other materials such as nitrogen or potassium.

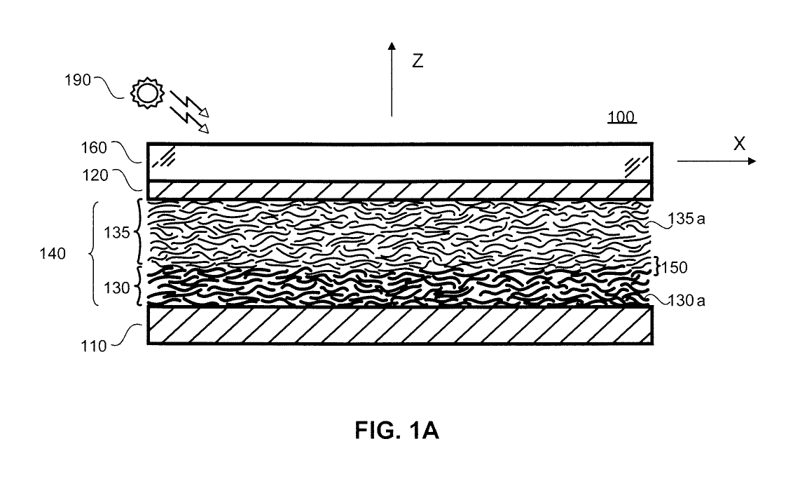

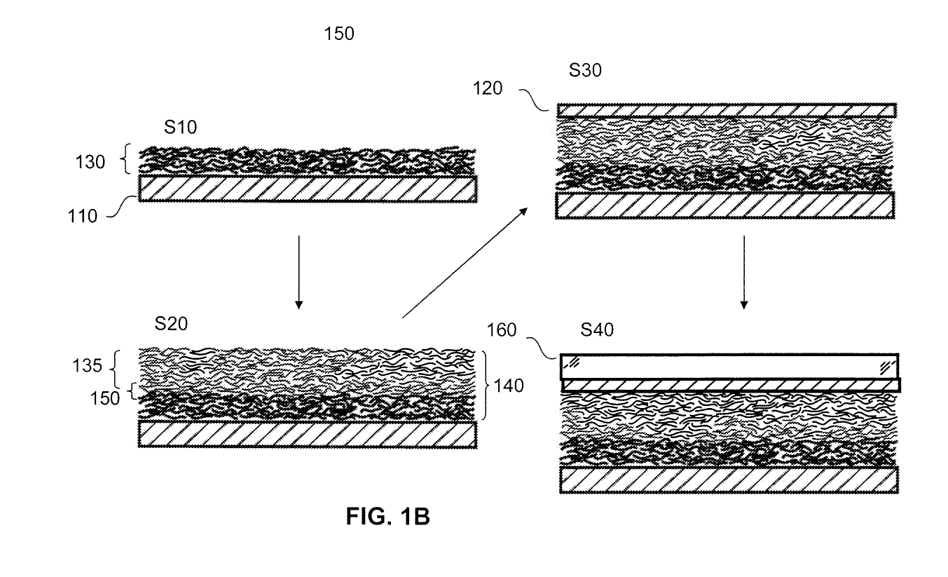

FIG. 1A is a diagram illustrating a nanotube based p-n junction PV device 100 according to one exemplary embodiment of the present disclosure. The device 100 comprises a first electrode element 110, a second electrode element 120, and a layer 140 of semiconducting elements disposed between the first and second electrode elements 110 and 120. Such electrode elements may also be referred to herein simply as electrodes. A transparent protective layer 160, e.g., any suitable polymer or glass coating transparent to visible and ultraviolet light, is disposed at an upper surface of the second electrode element 120. Use of terminology herein such as upper and lower, inner and outer, vertical and horizontal, etc., is for convenience and should not be construed as limiting in any way unless indicated otherwise. Moreover, use of the word “on” such as one layer being disposed on another, does not preclude the presence of intervening layers or structures.

The layer 140 of semiconducting elements can comprise a fabric of semiconducting carbon nanotubes (CNTs) having a first conductivity type, which in this example is provided by a layer 135 of p-type carbon nanotubes (comprised of a plurality of individual p-type carbon nanotubes 135a). In this example, the layer 140 of semiconducting elements further comprises a plurality of semiconducting nanostructures, provided in this example by a layer 130 of n-type (second conductivity type) nanotubes (comprised of a plurality of individual n-type carbon nanotubes 130a), which can also be in the form of a fabric of nanotubes. Of course the first and second conductivity types could be reversed such that layer 130 was p-type and layer 135 was n-type. A nanostructure as referred to herein for the purposes of the present disclosure refers a structure having at least one dimension ranging in size from 1 nm to 100 nanometers. As shown in FIG. 1A, the layer of semiconducting elements 140 can be disposed between the electrode elements 110 and 120 in a vertical direction Z that is perpendicular to an in-plane direction X (i.e., the layers are disposed one relative to another in the vertical Z direction). The thickness of the layer 135 of carbon nanotubes may range from 1 to 300 microns, e.g. about 1, 2, 5, 50, 100, 200, 300 microns in thickness. In particular it is advantageous for the layer 135 of p-type nanotubes to be of sufficient thickness to enhance the likelihood of photon absorption in that layer. The thickness of the layer 130 of n-type nanotubes may be somewhat thinner and may range from 0.1 to 0.5 microns, for example, e.g., 0.1, 0.2, 0.3, 0.4, 0.5 microns in thickness, but thicker layers can also be used.

A fabric of semiconducting carbon nanotubes as referred to herein for the present disclosure comprises a layer of multiple, interconnected carbon nanotubes. A fabric of nanotubes (or nanofabric), in the present disclosure, e.g., a non-woven CNT fabric, may, for example, have a structure of multiple entangled nanotubes that are irregularly arranged relative to one another. Alternatively, or in addition, for example, the fabric of nanotubes for the present disclosure may possess some degree of positional regularity of the nanotubes, e.g., some degree of parallelism along their long axes. The fabrics of nanotubes retain desirable physical properties of the nanotubes from which they are formed. The fabric preferably has a sufficient amount of nanotubes in contact so that at least one electrically semi-conductive pathway exists from a given point within the fabric to another point within the fabric. Individual nanotubes may typically have a diameter of about 1-2 nm and may have lengths ranging from a few microns to about 200 microns, for example. The nanotubes may curve and occasionally cross one another. Gaps in the fabric, i.e., between nanotubes either laterally or vertically, may exist. Such fabrics may comprise single-walled nanotubes, multi-walled nanotubes, or both. The fabric may have small areas of discontinuity with no tubes present. The fabric may be prepared as an individual layer or as multiple fabric layers, one formed upon another. The thickness of the fabric can be chosen as thin as substantially a monolayer of nanotubes or can be chosen much thicker, e.g., tens of nanometers to hundreds of microns in thickness. The porosity of the fabrics can be tuned to generate low density fabrics with high porosity or high density fabrics with low porosity. The porosity and thickness can be chosen as desired depending upon the application at hand. Such fabrics can be prepared by growing nanotubes using chemical vapor deposition (CVD) processes in conjunction with various catalysts, for example. Other methods for generating such fabrics may involve using spin-coating techniques and spray-coating techniques with preformed nanotubes suspended in a suitable solvent. Nanoparticles of other materials can be mixed with suspensions of nanotubes in such solvents and deposited by spin coating and spray coating to form fabrics with nanoparticles dispersed among the nanotubes. Such exemplary methods are described in more detail in the related art cited in the Background section of this disclosure.

The device 100 also includes a charge-separating junction 150 formed at the layer 140 of semiconducting elements. In particular, in this example, the charge-separating junction 150 is a p-n junction formed at the interface of the two semiconductor carbon nanotube layers (130 and 135). A charge-separating junction as referred to herein means a junction between two materials for which a difference in electrical characteristics, e.g., work functions or Fermi energies, causes a separation of charge, i.e., electrons and holes, at the junction. A p-n junction formed at an interface between a p-type semiconductor and an n-type semiconductor is one type of charge-separating junction. As discussed elsewhere herein in connection with other exemplary embodiments, a Schottky barrier formed at an interface of a metal and a semiconductor is another type of charge-separating junction. Because of the charge separation, a potential barrier or junction voltage is created at the junction. At the interface of the two semiconductor layers (130 and 135) the p-n junction 150 rectifies current flowing through the PV device 100.

The layer of semiconducting elements 140 has first side (at the upper surface of electrode 110) and a second side (at the lower surface of electrode 120). The first side of the layer 140 of semiconducting elements is electrically coupled to said first electrode element 110, and second side of the layer 140 of semiconducting elements is electrically coupled to the second electrode element 120. It will be appreciated that for elements to be electrically coupled for the present disclosure does not require that they be in direct electrical contact.

The first electrode element 110 can be formed of a metal such as a high work function metal such as, but not limited to, copper, gold, nickel, platinum, and ITO so as to make an ohmic contact or near-ohmic contact with the n-type carbon nanotube layer 130. The second electrode element 120 can also be formed of a metal such as a high work function metal such as, but not limited to, copper, gold, nickel, platinum, or formed from a conductive oxide such as, but not limited to, indium tin oxide (ITO) so as to form an ohmic or near-ohmic contact with the p-type carbon nanotube layer 135. Suitable electrode materials (e.g., metals) for forming ohmic or near-ohmic contacts can be selected by one skilled in the art by trial and error testing, for example, by measuring the electrical properties of the contact, e.g., resistance, to identify electrode materials that provide the desired contact properties. If the second electrode element 120 is formed from a non-transparent, electrically conductive material, e.g., a high work function metal, it can be formed in such a way as to allow light to penetrate through to the p-type carbon nanotube layer 135 such as, by depositing the second electrode material in long narrow strips or in a grid with gaps therebetween to permit light to pass through and impinge upon the carbon nanotube layer 135. The first electrode 110 can be supported by any suitable substrate (as can the other exemplary embodiments disclosed herein), if desired, such as a glass, polymer or semiconductor substrate, e.g., the first electrode 110 can be deposited on such a substrate by physical vapor deposition or chemical vapor deposition, for instance. The thickness of the first electrode element 110 may range from 1-100 microns, for instance. The thickness of the second electrode element 120 may also range from 1-100 microns, for example.

Photons 190 passing through the transparent protective layer 160 and the second electrode element 120 will reach the p-type carbon nanotube layer 135 and, in some cases, be absorbed. This absorption will cause a photoexcitation event, freeing a valance electron up into the conduction band where it can move freely through the nanotube layers 135 and 130. By placing a load or an electronic storage element (e.g., battery) across the first and second electrode elements (110 and 120), freed electrons within the p-type carbon nanotube layer 135 will tend to flow from the p-type carbon nanotube layer 135 into the n-type carbon nanotube layer 130, such that an electrical current is generated to the load or electronic storage element between the first and second electrode elements 110 and 120. In this way, solar energy (the impact of the photon 190) is converted into electrical current which can be used or stored by a circuit element placed across the first and second electrode elements 110 and 120.

FIG. 1B illustrates an exemplary method for making a PV device such as the exemplary PV device 100 shown in FIG. 1A, the method being generally applicable to other exemplary embodiments disclosed herein. First, a layer 140 of semiconducting elements is formed on a first electrode element. As shown in FIG. 1B, this can be accomplished by first depositing at step S10 a layer 130 of n-type carbon nanotubes (e.g., a fabric) on electrode element 110 and then by depositing at step S20 a layer 135 of p-type carbon nanotubes (e.g., a fabric) on layer 130. The layers 130 and 135 can be deposited at steps S10 and S20 by, for example, spray coating or spin coating using nanotubes suspended in a suitable solvent. Steps S10 and S20 can also be carried out, for example, by dipping the electrode element 110 into a liquid of nanotubes suspended in a solvent, by drawing the electrode element 110 through a liquid of nanotubes suspended in a solvent in successive steps, or by roll coating such as Gravure coating as mentioned previously. The deposited nanotube layer can be cured or dried, if desired, by illumination with photons or by heating in an oven or with a heating element positioned in proximity to the deposited layer. A drawing process for individual layers can be carried out continuously, if desired, such as in the case where the electrode element is flexible (e.g, is a conductive polymer sheet or metal layer deposited on a polymer sheet) and can be spooled from a feeding roller onto a take-up roller with liquid suspension and drying station positioned therebetween. The spool of processed material can be subsequently processed to deposit additional layers using an appropriate method of deposition for that layer. Each of the layers 130 and 135 may be formed in one operation, or they may be formed in multiple operations wherein each of the layers 130 and 135 is formed of multiple sub-layers (e.g., layer 130 and layer 135 could be formed by several spinning, spraying, dipping, drawing or roll-coating operations, each of which forms a sub-layer).

Exemplary solvents for spinning, spraying, dipping or drawing may include, for example, dimethylformamide, n-methyl pyrollidinone, n-methyl formamide, orthodichlorobenzene, paradichlorobenzene, 1,2, dichloroethane, alcohols, and water with appropriate surfactants, such as, for example, sodium dodecylsulfate or TRITON X-100. Other exemplary solvents may include ethyl lactate, dimethyl sulfoxide (DMSO), monomethyl ether, 4-methyl-2 pentanone, N-methylpyrrolidone (NMP), t-butyl alcohol, methoxy propanol, propylene glycol, ethylene glycol, gamma butyrolactone, benzyl benzoate, salicyladehyde, tetramethyl ammonium hydroxide and esters of alpha-hydroxy carboxylic acids. The addition of surfactants or other surface-active agents may be used but is not required. The nanotube concentration and deposition parameters, such as surface functionalization, spin-coating speed, temperature, pH, and time, can be adjusted to control deposition of monolayers or multilayers of nanotubes as desired.

The first electrode element 110 itself can be formed of a metal such as a high work function metal such as, but not limited to, copper, gold, nickel, platinum, and ITO so as to make an ohmic or near-ohmic contact with the n-type carbon nanotube layer 130. The first electrode element can be self-supporting, e.g., a layer of conductive polymer material, or it can be deposited, e.g., by physical vapor deposition or chemical vapor deposition, onto any suitable substrate, such as a glass, polymer or semiconductor substrate.

The method also comprises at step S30 forming a second electrode element 120 at a second (upper) side of the layer 140 of semiconducting elements. The second electrode element 120 can be formed from a transparent, electrically conductive material (such as, but not limited to, ITO) or formed from other electrode materials such as high work function metals such as, but not limited to, copper, gold, nickel, platinum in such a way as to allow light to penetrate through to the p-type carbon nanotube layer 135 (such as, by depositing the second electrode material in long narrow strips or in a grid with gaps therebetween to permit light to pass through and impinge upon the carbon nanotube layer 135). The first electrode 110 can be supported by any suitable substrate (as can the other exemplary embodiments disclosed herein), if desired, such as a glass, polymer or semiconductor substrate, e.g., the first electrode 110 can be deposited on such a substrate by physical vapor deposition or chemical vapor deposition, for instance. The first side of the layer 140 of semiconducting elements is electrically coupled to said first electrode element 110, and second side of the layer 140 of semiconducting elements is electrically coupled to the second electrode element 120.

The method also comprises forming at least one charge-separating junction at the layer of semiconducting elements, which in this example is provided by p-n junction 150 formed at step S20. The charge separating junction could be formed at an interface of the layer of semiconducting elements or within the layer of semiconducting elements as will be apparent from the various embodiments disclosed herein. The method comprises at step S40 forming a protective layer 160 at an upper surface of the second electrode element 120.

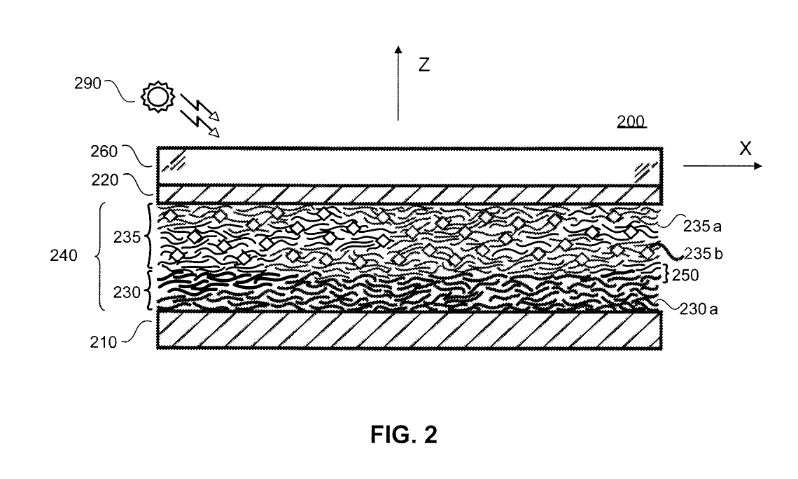

Referring now to FIG. 2, another exemplary p-n junction PV device 200 is illustrated. The PV device 200 depicted in FIG. 2 is nearly identical to the PV device 100 depicted in FIG. 1 except that a plurality of photosensitive particles 235b have been included in the p-type carbon nanotube layer 235 to increase photo generation. As noted above, examples of photosensitive particles include, but are not limited to, photosensitive dyes such as ruthenium-polypyridine and quantum dots made from III-V compounds such as GaAs, GaSb, and InP, or II-VI compounds such as CdS, CdSe, ZnS, and ZnSe. The photosensitive particles 235b may be incorporated into the layer 235 by, for example, spin coating, spray coating, drawing, or roll coating using a mixture of nanotubes and photosensitive particles suspended in a suitable solution.

The structure and operation of the p-n junction PV device 200 depicted in FIG. 2 is substantially identical to that of the p-n junction PV device 100 depicted in FIG. 1. Specifically, first electrode element 210 is analogous to first electrode element 110 in FIG. 1. The device 200 includes a layer 240 of semiconducting elements including a layer 235 of p-type carbon nanotubes and layer 230 of n-type carbon nanotubes. N-type carbon nanotube layer 230 (comprised of individual n-type carbon nanotubes 230a) is analogous to n-type carbon nanotube layer 130 in FIG. 1. P-type carbon nanotube layer 235 (comprised of individual p-type carbon nanotubes 240a and photosensitive particles 240b) is analogous to p-type carbon nanotube layer 140 in FIG. 1. The p-n junction 250 formed between n-type carbon nanotube layer 230 and p-type carbon nanotube layer 240 is analogous to the p-n junction 150 in FIG. 1. Second electrode element 220 is analogous to second electrode element 120 in FIG. 1. Transparent protective layer 260 is analogous to transparent protective layer 160 in FIG. 1. And exemplary photon element 290 is analogous to exemplary photon element 190 in FIG. 1.

The photosensitive particles 235b within p-type carbon nanotube layer 235 can increase the likelihood that a photon 290 passing through the layer 235 will be absorbed. In some embodiments, such particles 235b can be mixed with the individual p-type nanotube elements 235a prior to the formation of the p-type nanotube layer 235 and suspending in suitable solvents such as described above for deposition by spin coating, spray coating, dipping, drawing or roll coating the electrode element 210 with any previously deposited nanotube layers through a liquid of nanotubes and particles suspended in the solvent. Each of the layers 230 and 235 may be formed in one operation, or they may be formed in multiple operations wherein each of the layers 230 and 235 is formed of multiple sub-layers (e.g., layer 230 and layer 235 could be formed by several spinning, spraying, dipping or drawing operations, each of which forms a sub-layer). Such a process—that is forming a composite nanotube layer comprised of individual nanotube elements and nanoscopic particles—is described in U.S. patent application Ser. No. 12/274,033 to Ghenciu et al. These photo sensitive particles 240b can include, but are not limited to, photo sensitive dyes and quantum dots such as described above.

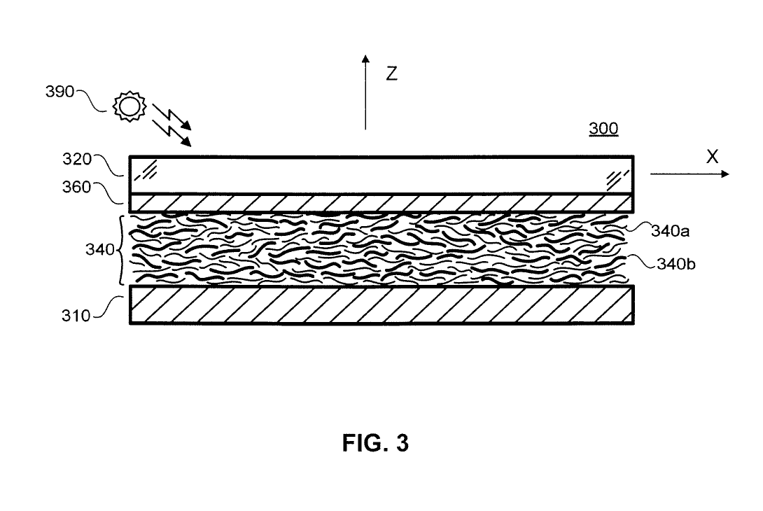

FIG. 3 is a diagram illustrating an exemplary nanotube based bulk hetero junction PV device 300 according to one embodiment of the present disclosure. A mixed layer 340 of p-type carbon nanotube elements 340a and n-type carbon nanotube elements 340b is formed over a first electrode element 310 by methods already explained elsewhere herein, e.g., by suspending both p-type and n-type carbon nanotubes in a suitable solvent and depositing the mixture of p-type and n-type carbon nanotubes by spin coating, spray coating, dipping, drawing, or roll coating. Within such a device, electron donor elements (the p-type carbon nanotube elements 340a) and electron acceptor elements (the n-type carbon nanotube elements 340b) are mixed together on a nanometer scale. That is, both types of semiconducting elements are separated by only nanometers within the mixed layer 340. In this way, there are numerous individual p-n junctions established within the layer 340, and the mixed nanotube layer 340 provides very efficient carrier diffusion of photoexcited electrons (freed when photons 390 are absorbed by p-type carbon nanotube elements 340a) through the PV device 300.

First electrode element 310—formed of a metal such as a high work function metal such as, but not limited to, copper, gold, nickel, and platinum—makes an ohmic or near-ohmic contact with a first side of the mixed nanotube layer 340. A second electrode element 320—also formed of a high work function metal or formed from a conductive oxide such as, but not limited to, indium tin oxide (ITO)—forms an ohmic or near-ohmic contact with a second side of mixed nanotube layer 340. This second electrode element 320 can be formed from a transparent material (such as, but not limited to, ITO) or formed in such a way as to allow light to penetrate through to mixed nanotube layer 340 (such as, by depositing the second electrode material in long narrow strips or in a grid). A transparent protective layer 360 is applied over the second electrode element 320.

Photons 390 passing through the transparent protective layer 360 and the second electrode element 320 will reach the mixed nanotube layer 340 and, in some cases, be absorbed by a p-type carbon nanotube element 340a. This absorption will cause a photoexcitation event, freeing a valance electron up into the conduction band where it can move freely through the mixed nanotube layer 340. By placing a load or an electronic storage element across the first and second electrode elements (310 and 320), freed electrons within mixed nanotube layer 340 will tend to flow through the mixed nanotube layer 340. In this way, solar energy (the impact of the photon 390) is converted into electrical current which can be used or stored by a circuit element placed across the first and second electrode elements 310 and 320.

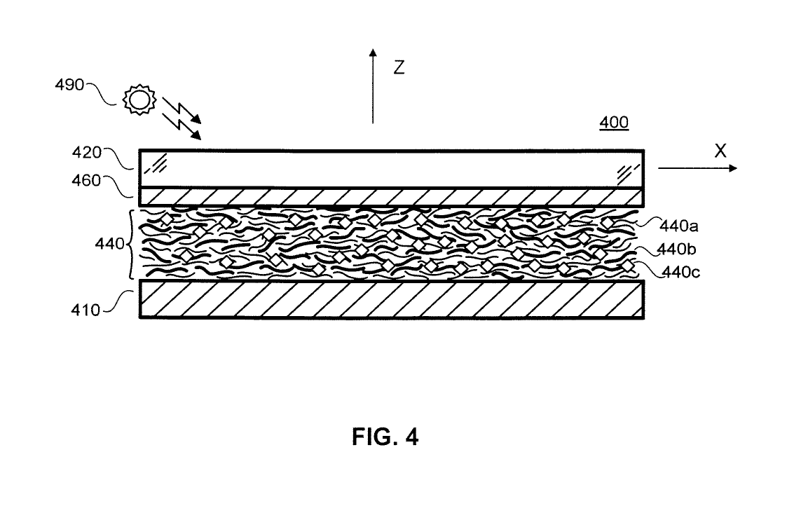

Referring now to FIG. 4, another bulk hetero junction PV device 400 is illustrated. The PV device 400 depicted in FIG. 4 is nearly identical to the PV device 300 depicted in FIG. 3 except that a plurality of photosensitive particles 440c such as described above have been included in the mixed nanotube layer 440 to increase photo generation.

The structure and operation of the bulk hetero-junction PV device 400 depicted in FIG. 4 is substantially identical to that of the bulk hetero-junction PV device 300 depicted in FIG. 3. Specifically, first electrode element 410 is analogous to first electrode element 310 in FIG. 3. Mixed nanotube layer 440 (comprised of individual p-type carbon nanotube elements 440a, individual n-type carbon nanotubes 440b, and photosensitive particles 440c) is analogous to mixed nanotube layer 340 in FIG. 3. Second electrode element 420 is analogous to second electrode element 320 in FIG. 3. Transparent protective layer 460 is analogous to transparent protective layer 360 in FIG. 3. And exemplary photon element 490 is analogous to exemplary photon element 390 in FIG. 3.

The photosensitive particles 440c within mixed nanotube layer 440 increase the likelihood that a photon 490 passing through the layer 440 will be absorbed. In some embodiments, such particles 440c can be mixed with the individual p-type nanotube elements 440a and the individual n-type nanotube elements 440b prior to the formation of the mixed nanotube layer 440. The mixed nanotube layer 440 can be formed by methods already explained elsewhere herein, e.g., by suspending both p-type and n-type carbon nanotubes in a suitable solvent and depositing the mixture of p-type and n-type carbon nanotubes by spin coating, spray coating, dipping, drawing or roll coating., e.g., such as described in U.S. patent application Ser. No. 12/274,033 to Ghenciu et al. These photosensitive particles 440c can include, but are not limited to, photosensitive dyes and quantum dots such as described above.

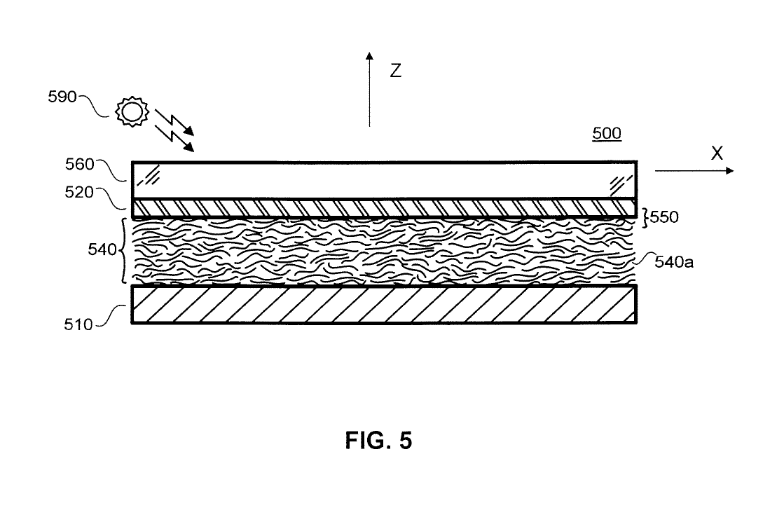

FIG. 5 is a diagram illustrating an exemplary nanotube based Schottky barrier PV device 500 according to one embodiment of the present disclosure. In this example a charge-separating junction 550 is provided by a Schottky barrier 550 instead of a p-n junction. A layer semiconducting nanotubes 540 (comprised of a plurality of individual semiconducting nanotube elements 540a) is deposited over a first electrode element 510 such as described above in connection with other embodiments. The nanotube elements 540a can be p-type, or the nanotube elements 540a can be n-type. This first electrode element—comprised of a metal such as a high work function metal such as, but not limited to, copper, gold, nickel, and platinum, e.g, formed by any suitable deposition method such as described elsewhere herein—forms an ohmic or near-ohmic contact with the semiconducting nanotube layer 540.

A second electrode element 520—comprised of a metal such as a low work function metal (such as, but not limited to, calcium, potassium, manganese, silver, aluminum, zinc, titanium, and iron)—can be deposited using any suitable deposition method such as described elsewhere herein and forms a Schottky barrier 550 at the interface between the semiconducting nanotube layer 540 and the second electrode element 520. As with the p-n junction of the PV devices (100 and 200) depicted in FIGS. 1 and 2, Schottky barrier 550 creates a junction voltage across the interface between the nanotube layer 540 and the second electrode element 520 which rectifies current flowing through the PV device 500. Suitable electrode materials (e.g., metals) for forming Schottky barriers with the nanotube layer can be selected by one skilled in the art by trial and error testing, for example, by measuring the electrical properties of the contact, e.g., resistance and rectifiying behavior, to identify electrode materials that provide the desired rectifiying properties for the Schottky barrier.

In this embodiment of the present disclosure, second electrode element 520 is formed in such a way as to allow light to penetrate through to the semiconducting nanotube layer 540 (such as, by depositing the second electrode material in long narrow strips or in a grid). A transparent protective layer 560 is applied over the second electrode element 520.

Photons 590 passing through the transparent protective layer 560 and the second electrode element 520 will reach the semiconducting nanotube layer 540 and, in some cases, be absorbed. This absorption will cause a photoexcitation event, freeing a valance electron up into the conduction band where it can move freely through the nanotube layer 540. By placing a load or an electronic storage element across the first and second electrode elements (510 and 520), freed electrons within the semiconducting nanotube layer 540 will tend to flow across the Schottky barrier 550 and into second electrode element 520. In this way, solar energy (the impact of the photon 590) is converted into electrical current which can be used or stored by a circuit element placed across the first and second electrode elements 510 and 520.

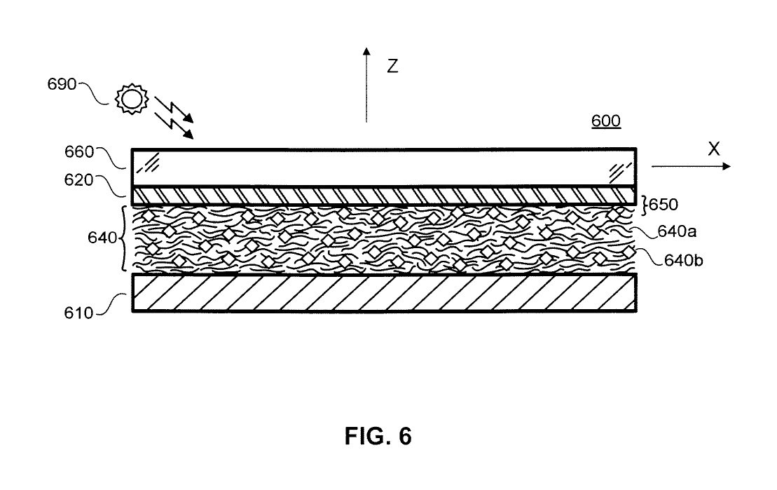

Referring now to FIG. 6, another exemplary Schottky barrier PV device 600 is illustrated. The PV device 600 depicted in FIG. 6 is nearly identical to the PV device 500 depicted in FIG. 5 except that a plurality of photosensitive particles 640b such as described above have been included in the semiconducting nanotube layer 640 to increase photo generation.

The structure and operation of the Schottky barrier PV device 600 depicted in FIG. 6 is substantially identical to that of the Schottky barrier PV device 500 depicted in FIG. 5. Specifically, first electrode element 610 is analogous to first electrode element 510 in FIG. 5. Semiconducting nanotube layer 640 (comprised of individual semiconducting nanotube elements 640a and photosensitive particles 640b) is analogous to semiconducting nanotube layer 550 in FIG. 5. Second electrode element 620 is analogous to second electrode element 520 in FIG. 5. Schottky barrier 650 is analogous to the Schottky barrier 550 in FIG. 5. Transparent protective layer 660 is analogous to transparent protective layer 560 in FIG. 5. And exemplary photon element 690 is analogous to exemplary photon element 590 in FIG. 5.

The photosensitive particles 640b within semiconducting nanotube layer 640 increase the likelihood that a photon 690 passing through the layer 640 will be absorbed. In some embodiments, such particles 640b can be mixed with the individual nanotube elements 640a prior to the formation of the semiconducting nanotube layer 640. Layer 640 can be formed by methods already explained elsewhere herein, e.g., by suspending both p-type and n-type carbon nanotubes in a suitable solvent and depositing the mixture of p-type and n-type carbon nanotubes by spin coating, spray coating, dipping, drawing, or roll coating e.g., such as described in U.S. patent application Ser. No. 12/274,033 to Ghenciu et al. These photosensitive particles 640b can include, but are not limited to, photosensitive dyes and quantum dots such as described above.

While Schottky barrier PV devices—such as the devices (500 and 600) depicted in FIGS. 5 and 6—can provide effective voltage generation in many applications, such devices can be limited, in some cases, by the low open circuit voltage and dark current typical of the Schottky barrier structure. To address this issue, a modified Schottky barrier PV device can be provided that utilizes a metal-insulator-semiconductor (MIS) three layer structure. A very thin layer of insulating material is placed between a layer of semiconducting material and a layer of metal such as a low work function metal. A Schottky barrier is formed across the layer of insulating material. This layer of insulating material allows minority carriers (electrons for p-type semiconducting material and holes for n-type semiconducting material) to pass through into the metal layer while preventing majority carriers (holes for p-type semiconducting material and electrons for n-type semiconducting material) from passing through. In this way, dark current—essentially the reverse bias leakage current introduced by the Schottky barrier—is significantly reduced, allowing for a more efficient PV device.

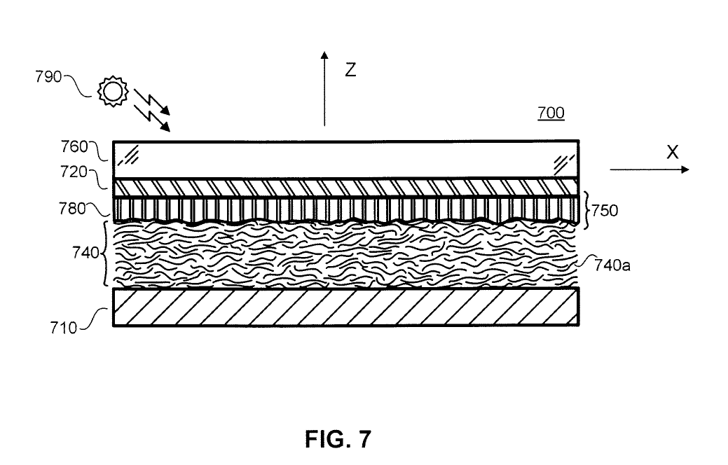

For example, FIG. 7 is a diagram illustrating an exemplary nanotube based MIS PV device 700 according to one embodiment of the present disclosure. A layer of semiconducting nanotubes 740 (comprised of a plurality of individual semiconducting carbon nanotubes 740a) is deposited over a first electrode element 710 such as by methods already disclosed herein. This first electrode element—comprised of a metal such as a high work function metal such as, but not limited to, copper, gold, nickel, and platinum—forms an ohmic or near-ohmic contact with the semiconducting nanotube layer 740.

A thin layer of insulating material 780—such as, but not limited to, silicon dioxide (SiO₂), titanium dioxide (TiO₂), gallium trioxide (Ga₂O₃), tantalum pentoxide (Ta₂O₅), aluminum oxide (Al₂O₃), and diamond—is deposited over the semiconducting nanotube layer 740 using any suitable deposition method. Layer 780 may be deposited by physical vapor deposition such as sputtering and electron-beam evaporation and may range in thickness from a few monolayers to several nanometers, e.g., 1, 2, 3 nanometers, for instance, so as to be thin enough to permit electrons to tunnel through that layer. A second electrode element 720—comprised of a metal such as a low work function metal (such as, but not limited to, calcium, potassium, manganese, silver, aluminum, zinc, titanium, and iron)—is deposited over the layer of insulating material 780. A Schottky barrier 750 is formed across the insulating material layer 780 between the semiconducting nanotube layer 740 and the second electrode element 720.

As within the Schottky barrier PV devices (500 and 600) depicted in FIGS. 5 and 6, Schottky barrier 750 forms a junction voltage between the nanotube layer 740 and the second electrode element 720 which rectifies current flowing through the PV device 700. In addition, the insulating layer 780—effectively situated within the formed Schottky barrier 750—significantly limits dark current within the PV device 700 by preventing majority carriers from passing through.

In this embodiment of the present disclosure, second electrode element 720 is formed in such a way as to allow light to penetrate through to the semiconducting nanotube layer 740 (such as, by depositing the second electrode material in long narrow strips or in a grid). A transparent protective layer 760 is applied over the second electrode element 720.

Photons 790 passing through the transparent protective layer 760 and the second electrode element 720 will reach the semiconducting nanotube layer 740 and, in some cases, be absorbed. This absorption will cause a photoexcitation event, freeing a valance electron up into the conduction band where it can move freely through the nanotube layer 740. By placing a load or an electronic storage element across the first and second electrode elements (710 and 720), freed electrons within the semiconducting nanotube layer 740 will tend to flow across the Schottky barrier 750 and into second electrode element 720. In this way, solar energy (the impact of the photon 790) is converted into electrical current which can be used or stored by a circuit element placed across the first and second electrode elements 710 and 720.

A consideration associated with the design and fabrication of MIS PV devices is forming very thin and uniform layers of insulating material between the semiconducting layer and metal layer. Within traditional silicon based MIS PV devices, such insulating layers tend to be highly brittle (limiting the durability of such a device) and include a number of pin hole defects (small gaps within the insulating layer which significantly limit the effectiveness of the insulating layer). However, by using a layer of semiconducting nanotubes as the semiconducting layer within a MIS PV device, a number of techniques for reliably depositing thin, uniform, and robust insulating layers are available.

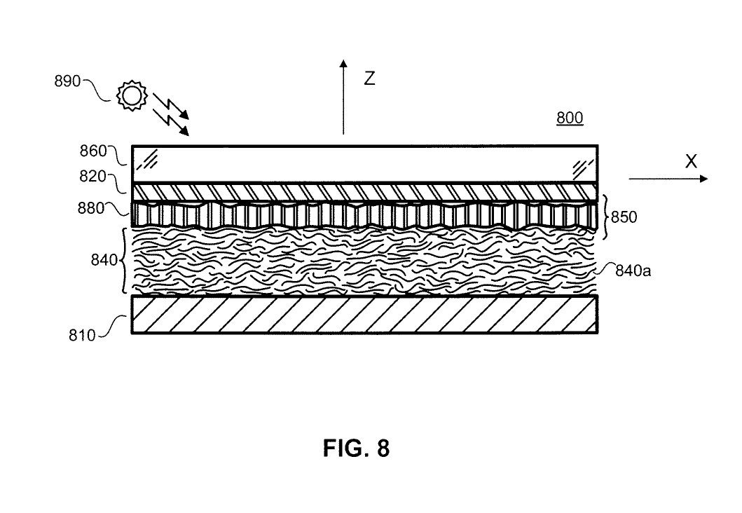

FIG. 8 depicts a MIS PV device 800 according to one embodiment of the present disclosure wherein insulating layer 880 can be formed in a conformal manner on the semiconducting nanotube layer 840. For example, such a conformal insulating layer 880 could be formed through chemical vapor deposition (CVD) of uniform nanometer size insulating material over the surface of the nanotube layer 840. In this way, the structure of the semiconducting nanotube layer itself can be used to reliably control the formation of a very thin, uniform insulating layer.

The structure and operation of the MIS PV device 800 depicted in FIG. 8 is substantially identical to that of the MIS PV device 700 depicted in FIG. 7. Specifically, first electrode element 810 is analogous to first electrode element 710 in FIG. 7. Semiconducting nanotube layer 840 (comprised of individual semiconducting nanotube elements 840a) is analogous to semiconducting nanotube layer 750 in FIG. 7. Insulating layer 880 is analogous to insulating layer 780 in FIG. 7. Second electrode element 820 is analogous to second electrode element 720 in FIG. 7. Schottky barrier 850 is analogous to Schottky barrier 750 in FIG. 7. Transparent protective layer 860 is analogous to transparent protective layer 760 in FIG. 7. And exemplary photon element 890 is analogous to exemplary photon element 790 in FIG. 7.

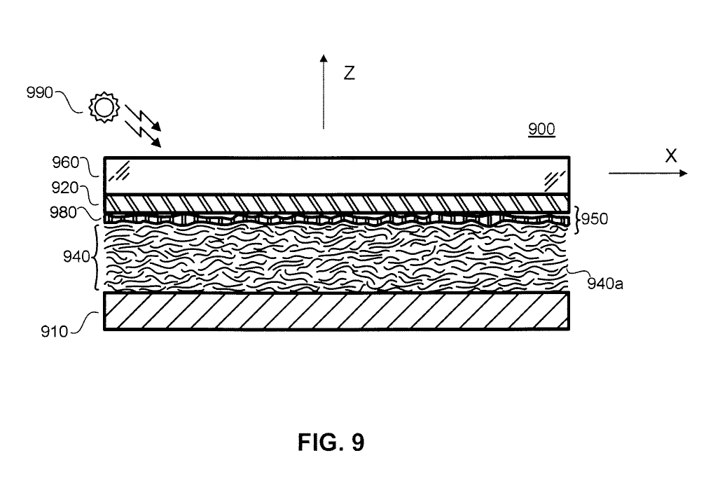

FIG. 9 depicts an exemplary MIS PV device 900 according to one embodiment of the present disclosure wherein insulating layer 980 has been formed using an atomic layer deposition (ALD) process. Within this embodiment, a plurality of dielectric precursor molecules 980a are dispersed over the surface of semiconducting nanotube layer 940. The dielectric precursor molecules 980a will tend to collect over the surface of the semiconducting nanotube layer 940, creating an insulating layer of uniform thickness following the nanostructure of the underlying nanotube layer 940. The ALD process is a surface limiting deposition process, therefore the surface of the nanotubes will be suitably modified to deposit the required insulating layer. ALD deposition can be controlled at a monolayer level and the thickness of the ALD deposited layer can be precisely controlled by controlling the number of ALD cycles performed. For example additional ALD operations can be performed to very precisely control the thickness of insulating layer 980, essentially increasing the thickness of the insulating layer 980 by the height of one dielectric precursor molecule with each operation. In this way, the structure of the semiconducting nanotube layer itself can be used to reliably control the formation of a very thin, uniform insulating layer. Relative to that shown in FIG. 8, the insulating layer 980 shown in FIG. 9 is somewhat thinner, and layer 980 may range in thickness from a few monolayers to about 1 nanometer. HERE

The structure and operation of the MIS PV device 900 depicted in FIG. 9 is substantially identical to that of the MIS PV device 700 depicted in FIG. 7. Specifically, first electrode element 910 is analogous to first electrode element 710 in FIG. 7. Semiconducting nanotube layer 940 (comprised of individual semiconducting nanotube elements 940a) is analogous to semiconducting nanotube layer 750 in FIG. 7. Insulating layer 980 is analogous to insulating layer 780 in FIG. 7. Second electrode element 920 is analogous to second electrode element 720 in FIG. 7. Schottky barrier 950 is analogous to Schottky barrier 750 in FIG. 7. Transparent protective layer 960 is analogous to transparent protective layer 760 in FIG. 7. And exemplary photon element 990 is analogous to exemplary photon element 790 in FIG. 7.

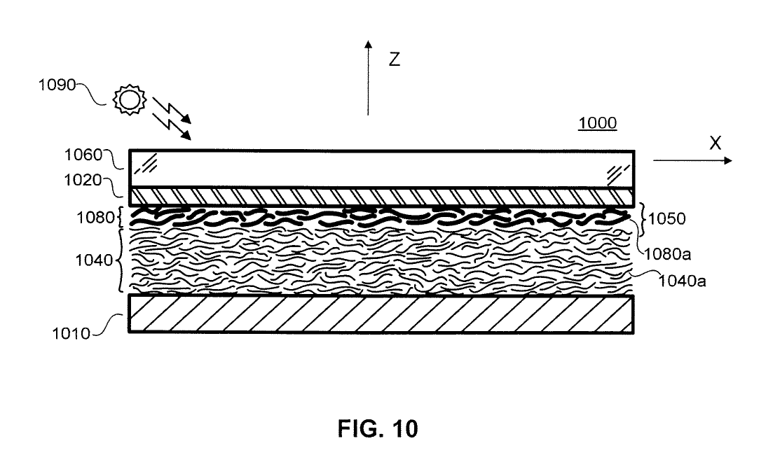

FIG. 10 depicts an exemplary MIS PV device 1000 according to one embodiment of the present disclosure wherein insulating layer 1080 has been formed by depositing a layer of nonconductive nanotube elements 1080a. A plurality of insulating nanotube structures can be used to create the thin layer of nonconductive nanotubes 1080, including, but not limited to, boron nitride nanotubes, double and multi-walled nanotubes, fluorinated single-walled carbon nanotubes, and other oxide and nitride nanotubes. Boron nitride nanotubes can be made, for example, by CVD or by ball milling amorphous boron with iron powder (as a catalyst) under an ammonia atmosphere followed by subsequent high temperature annealing, as known to those skilled in the art. Further, a network of conductive nanotubes can be rendered insulating by a plurality of methods, including, but not limited to, controlled exposure to reactive ion etching chemistries, gaseous exposures, and wet chemical modifications. A number of nanotube layer deposition methods (such as, but not limited to, spin coating spray coating and CVD, such as taught in U.S. Pat. No. 7,335,395 to Ward et al.) allow for the formation of a very thin layer—or, in some cases a monolayer substantially one nanotube thick—of nonconductive nanotube elements 1080a over semiconducting nanotube layer 1040. In this way, a nonconductive nanotube layer can be used to create a very thin, uniform insulating layer.

The structure and operation of the MIS PV device 1000 depicted in FIG. 10 is substantially identical to that of the MIS PV device 700 depicted in FIG. 7. Specifically, first electrode element 1010 is analogous to first electrode element 710 in FIG. 7. Semiconducting nanotube layer 1040 (comprised of individual semiconducting nanotube elements 1040a) is analogous to semiconducting nanotube layer 750 in FIG. 7. Insulating layer 1080 is analogous to insulating layer 780 in FIG. 7. Second electrode element 1020 is analogous to second electrode element 720 in FIG. 7. Schottky barrier 1050 is analogous to Schottky barrier 750 in FIG. 7. Transparent protective layer 1060 is analogous to transparent protective layer 760 in FIG. 7. And exemplary photon element 1090 is analogous to exemplary photon element 790 in FIG. 7.

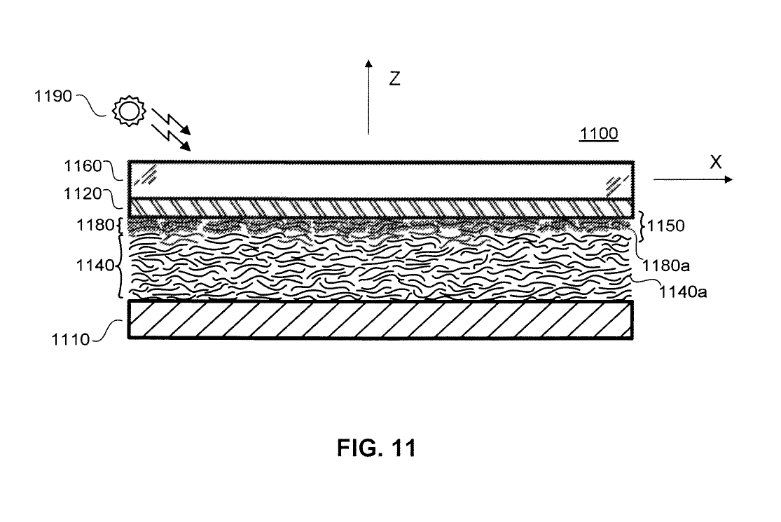

FIG. 11 depicts an exemplary MIS PV device 1100 according to one embodiment of the present disclosure wherein insulating layer 1180 has been formed by depositing a layer of nanotube elements 1080a coated with a plurality of nonconductive nanoparticles. A number of nanotube layer deposition methods (such as, but not limited to, spin coating, spray coating and CVD such as taught in U.S. Pat. No. 7,335,395 to Ward et al.) allow for the formation of a very thin layer—or, in some cases a monolayer substantially one nanotube thick—of nanoparticle coated nanotube elements 1080a over semiconducting nanotube layer 1040. In this way, a nanotube layer can be used to create a very thin, uniform insulating layer.

Nonconductive nanoparticles can be realized from a plurality of materials including, but not limited to, silicon dioxide, aluminum oxide, titanium oxide, silicon nitride, and aluminum nitride.

Further, nonconductive nanoparticles can be adhered to a nanotube element via a plurality of methods, including, but not limited to:
(1) Generation of pre-functionalized nanoparticles which are subsequently coupled to the surface of the nanotube element during the formation of the nanotube solution, as described in U.S. Pat. No. 7,375,369 to Sen et al., incorporated herein by reference in its entirety, or during fabrication of the device presented here;
(2) Polymer wrapping of the nanotube element surface to generate a pre-functionalized surface which then couples to nanoparticles having complimentary functional groups (typical polymers for such a method include, but are not limited to, di-block co-polymers such as ionomers, polypeptides, and DNA);
(3) Fluorination of the nanotube element surface to create fluorinated bands on said surface which then acts as a chemical mask for nanoparticle attachment on said surface (such a chemical mask can either act as a positive mask or a negative mask depending on functional groups on the nanoparticles);
(4) Deposition of nanoparticles on electrode during fabrication which permit functionalization of nanotubes during subsequent processing.

The structure and operation of the MIS PV device 1100 depicted in FIG. 11 is substantially identical to that of the MIS PV device 700 depicted in FIG. 7. Specifically, first electrode element 1110 is analogous to first electrode element 710 in FIG. 7. Semiconducting nanotube layer 1140 (comprised of individual semiconducting nanotube elements 1140a) is analogous to semiconducting nanotube layer 750 in FIG. 7. Insulating layer 1180 is analogous to insulating layer 780 in FIG. 7. Second electrode element 1120 is analogous to second electrode element 720 in FIG. 7. Schottky barrier 1150 is analogous to Schottky barrier 750 in FIG. 7. Transparent protective layer 1160 is analogous to transparent protective layer 760 in FIG. 7. And exemplary photon element 1190 is analogous to exemplary photon element 790 in FIG. 7.

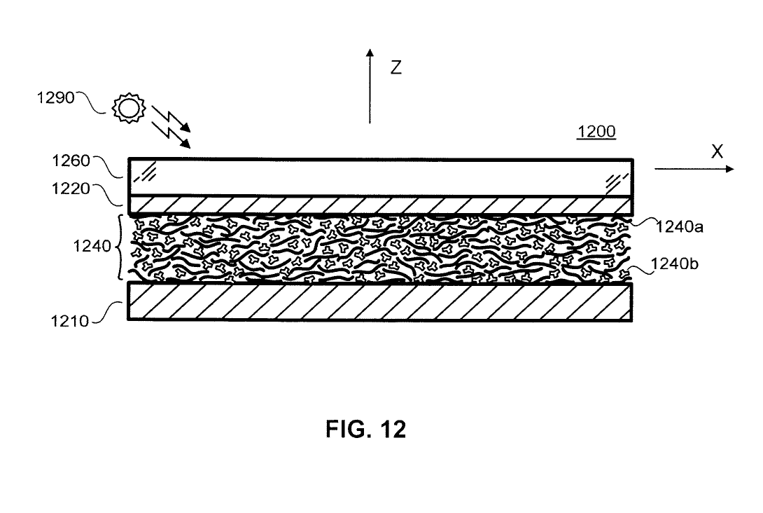

FIG. 12 is a diagram illustrating a nanotube based bulk hetero junction PV device 1200 according to one embodiment of the present disclosure. A composite active layer 1240 of semiconducting carbon nanotube elements 1240a and semiconducting nanostructures such as semiconductor nanoparticles 1240b is formed over a first electrode element 1210. The semiconductor particles can include, for example, doped amorphous silicon nanoparticles, doped crystalline silicon nanoparticles, doped amorphous germanium nanoparticles, doped crystalline germanium nanoparticles, CdS nanoparticles, CdSe nanoparticles, or other types of III-V or II-VI semiconductor nanoparticles. In some aspects of this embodiment of the present disclosure, the semiconducting carbon nanotube elements 1240a are substantially all p-type carbon nanotubes and the semiconductor (e.g., silicon) nanoparticles 1240b are doped such that they are n-type elements. In other aspects of the present disclosure, the semiconducting carbon nanotube elements 1240a are substantially all n-type carbon nanotubes and the semiconductor nanoparticles 1240b are doped such that they are p-type elements.

Within all such aspects, electron donor elements (the p-type elements) and electron acceptor elements (the n-type elements) are mixed together on a nanometer scale. That is, both types of semiconducting elements are separated by only nanometers within the composite active layer 1240. In this way, the composite active layer 1240 provides very efficient carrier diffusion of photoexcited electrons (freed when photons 1290 are absorbed by p-type elements within composite active layer) through the PV device 1200.

First electrode element 1210—formed of a metal such as a high work function metal such as, but not limited to, copper, gold, nickel, and platinum—makes an ohmic or near-ohmic contact with a first side of composite active layer 1240. A second electrode element 1220—also formed of a metal such as a high work function metal or formed from a conductive oxide such as, but not limited to, indium tin oxide (ITO)—forms an ohmic or near-ohmic contact with a second side of composite active layer 1240. This second electrode element 1220 can be formed from a transparent material (such as, but not limited to, ITO) or formed in such a way as to allow light to penetrate through to mixed nanotube layer 1240 (such as, by depositing the second electrode material in long narrow strips or in a grid). A transparent protective layer 1260 is applied over the second electrode element 1220.

Photons 1290 passing through the transparent protective layer 1260 and the second electrode element 1220 will reach the composite active layer 1240 and, in some cases, be absorbed by a p-type element within the composite active layer 1240. This absorption will cause a photoexcitation event, freeing a valance electron up into the conduction band where it can move freely through the composite active layer 1240. By placing a load or an electronic storage element across the first and second electrode elements (1210 and 1220), freed electrons within composite active layer 1240 will tend to flow through the composite active layer 1240. In this way, solar energy (the impact of the photon 1290) is converted into electrical current which can be used or stored by a circuit element placed across the first and second electrode elements 1210 and 1220.

The composite active layer 1240 may additionally comprise a plurality of photosensitive particles such as photosensitive dye particles or quantum dots as disclosed elsewhere herein in addition to the carbon nanotube elements and semiconductor nanostructures referred to above.

The PV devices described within the present disclosure all make use of electrode elements to make ohmic connections with semiconducting nanotube layers. While metallic layers such as high work function metallic layers are well suited to form these electrode elements, in some applications it is desirable to use layers of conductive nanotube elements (metallic nanotubes) to realize these electrode elements.

For example, nanotube layers are highly conformal when applied over an underlying material layer. In some aspects of the present disclosure, metallic nanotube layers could be used to realize PV devices of complex geometry including, but not limited to, curved, angled, and multi-faced PV devices. Also, in some cases metallic nanotubes can be formed into very thin layers which are both substantially transparent and highly conductive. For example, U.S. patent application Ser. No. 12/553,695 to Sen et al., incorporated herein by reference in its entirety, teaches the formation of thin, anisotropic nanotube fabric layers which would be well suited for forming transparent electrode elements within many of the PV devices taught in the present disclosure (the second electrode element 120 within the PV device 100 of FIG. 1, for example, which requires a substantially transparent electrode element to make an ohmic connection with the p-type nanotube layer 140).

Further, nanotube layers are substantially flexible. A PV device comprising metallic nanotube layer electrode elements and semiconducting nanotube layer PV material can be used to form large, flexible PV devices. For example, such PV devices could be constructed over a large flexible substrate (such as, but not limited to, a plastic sheet) such as to realize a large, conformal PV device.

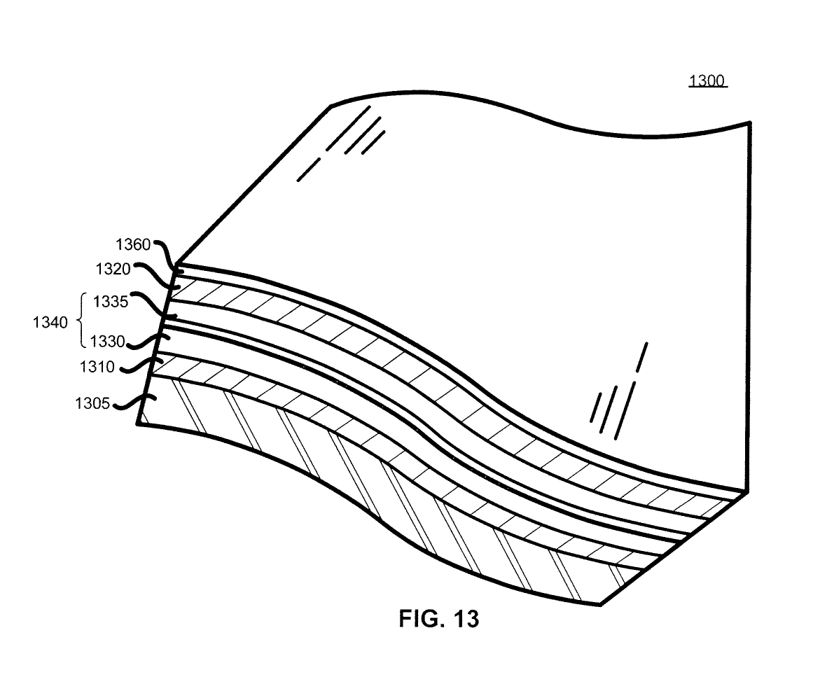

FIG. 13 illustrates such a flexible p-n junction PV device 1300. A first electrode element 1320—comprised of a flexible layer of metallic carbon nanotubes or other conducting material such as a metal, e.g., a high work function metal—is formed over a flexible substrate 1305. A layer of semiconducting elements 1340 comprising a layer of p-type carbon nanotubes 1335 and n-type carbon nanotubes 1330 is formed over the first electrode 1310. In particular, a layer of n-type carbon nanotubes 1330 is formed over the first electrode 1310, and a layer of p-type carbon nanotubes 1335 is formed over the n-type nanotube layer 1330. A substantially transparent and highly conductive layer of metallic nanotubes is used to form second electrode element 1320. And a transparent protective element 1360 is deposited over second electrode element 1360. In this way a substantially flexible p-n junction PV device 1300 is realized. It should be noted that while the exemplary PV device 1300 is a p-n junction type, the methods of the present disclosure are not limited in this regard. Indeed, it will be clear to those skilled in the art from the preceding discussion that many of the PV devices taught within the present disclosure could be rendered into a flexible structure as shown in FIG. 13.

Further, while the different PV devices of the present disclosure are all depicted with transparent protective layers (layer 160 in FIG. 1, for example), the methods of the present disclosure are not limited in this regard. The inclusion of such layers within the illustrations of FIGS. 1-11 has been used only for the sake of clarity within the discussion of the embodiments of the present disclosure. Indeed, it will be clear to those skilled in the art that such protective layers are not required for the function of the PV devices (as described herein) but are typically employed in practical applications to form more robust PV devices.

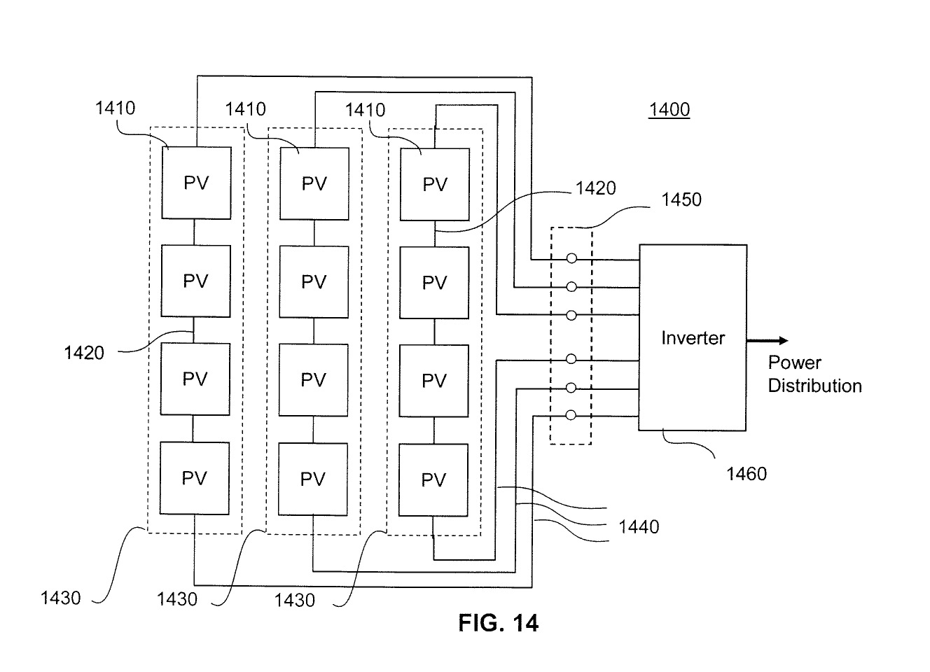

FIG. 14 illustrates an exemplary photovoltaic power generating system 1400 according to the present disclosure The system 1400 comprises multiple photovoltaic devices 1410 electrically coupled together, e.g., via electrical connections 1420. The system 1400 also comprises an electrical inverter 1460 electrically coupled to an output section 1450 of the multiple photovoltaic devices 1410. For example, PV devices 1410 can be coupled in series to form strings 1430, and the strings 1430 can be electrically coupled in parallel, e.g., via electrical connections 1440, e.g., at the output section 1450 (a junction box, for instance) or at the inverter 1460 itself. The strings 1430 could also be directly coupled together in parallel, e.g., with the use of blocking diodes so as to avoid imposition of reverse currents in devices 1410 that might be shadowed from illumination by photons. As will be appreciated by those of ordinary skill in the art, the inverter 1460 receives a DC electric current from the output section 1450 and converts the DC electric current to an AC electric current.

Each of the multiple photovoltaic devices 1410 can be formed according to the examples disclosed herein. As explained previously herein, such PV devices comprise a first electrode element, a second electrode element, and a layer of semiconducting elements disposed between the first and second electrode elements. The layer of semiconducting elements comprises a fabric of semiconducting carbon nanotubes having a first conductivity type such as explained previously herein, and at least one charge-separating junction is formed at the layer of semiconducting elements. The layer of semiconducting elements of each device 1410 has a first side and a second side, wherein the first side of the layer of semiconducting elements is electrically coupled to said first electrode element, and wherein the second side of said layer of semiconducting elements is electrically coupled to said second electrode element.

A flexible PV device such as illustrated in FIG. 13, wherein both electrode elements are transparent, can be useful as a power generating window coating. For example, such a flexible device could be applied to windows of a building in much the same say that window tint film is applied to automobile windows. Those PV devices could be electrically coupled together, e.g., such as schematically illustrated in FIG. 14 to an inverter to provide a high-output power generating system.

Although the present invention has been described in relation to particular embodiments thereof, many other variations and modifications and other uses will become apparent to those skilled in the art. Therefore the present invention not be limited by the specific disclosure herein.

What is claimed is:

1. A photovoltaic device, comprising:
a first electrode element;
a second electrode element;
at least one layer of semiconducting elements disposed between said first and second electrode elements, said at least one layer of semiconducting elements comprising a fabric of semiconducting carbon nanotubes having a first conductivity type, said at least one layer of semiconducting elements having a first side and a second side; and
at least one charge-separating junction formed at said at least one layer of semiconducting elements,
wherein said first side of said at least one layer of semiconducting elements is electrically coupled to said first electrode element, and
wherein said second side of said at least one layer of semiconducting elements is electrically coupled to said second electrode element.

2. The photovoltaic device of claim 1, wherein said at least one layer of semiconducting elements further comprises a plurality of semiconducting nanostructures, and wherein said at least one charge-separating junction is a p-n junction formed between said carbon nanotubes and said semiconducting nanostructures.

3. The photovoltaic device of claim 1 wherein at least one of said first electrode element and said second electrode element is substantially transparent.

4. The photovoltaic device of claim 1 wherein at least one of said first electrode element and said second electrode element is shaped such as to expose at least part of said at least one layer of semiconducting elements to a light source.

5. The photovoltaic device of claim 1 wherein said first electrode element and said second electrode element are flexible.

6. The photovoltaic device of claim 1 wherein said at least one layer of semiconducting elements further includes a plurality of photosensitive particles.

7. The photovoltaic device of claim 6 wherein said plurality of photosensitive particles includes photosensitive dye particles.

8. The photovoltaic device of claim 6 wherein said plurality of photosensitive particles includes quantum dots.

9. The photovoltaic device of claim 2 wherein said semiconducting nanostructures comprise semiconducting carbon nanotubes of a second conductivity type.

10. The photovoltaic device of claim 2 wherein said plurality of carbon nanotubes of the first conductivity type comprises a first layer of carbon nanotubes and wherein said plurality of semiconducting nanostructures of the second conductivity type comprises a second layer of carbon nanotubes disposed on said first layer of carbon nanotubes.

11. The photovoltaic device of claim 2 wherein said plurality of semiconducting nanostructures of the second conductivity type comprises carbon nanotubes of a second conductivity type, and wherein said carbon nanotubes of said first conductivity type and said carbon nanotubes of said second conductivity type are intermingled to form a heterogeneous mixture.

12. The photovoltaic device of claim 2 wherein said semiconducting nanostructures comprise semiconducting nanoparticles of a second conductivity type.

13. The photovoltaic device of claim 12 wherein said semiconducting nanoparticles comprise doped silicon particles.

14. The photovoltaic device of claim 12 wherein said plurality of semiconducting nanotube elements are substantially all p-type and said plurality of semiconducting nanoparticles are substantially all n-type.

15. The photovoltaic device of claim 12 wherein said plurality of semiconducting nanotube elements are substantially all n-type and said plurality of semiconducting nanoparticles are substantially all p-type.

16. The photovoltaic device of claim 12 wherein said at least one layer of semiconducting elements further includes a plurality of photosensitive particles.

17. The photovoltaic device of claim 12 wherein said plurality of semiconducting nanotube elements and said plurality of semiconducting nanoparticles are intermingled to form a heterogeneous mixture.

18. The photovoltaic device of claim 1, wherein said at least one charge-separating junction is a Schottky barrier formed at an interface between said second electrode and said at least one layer of semiconducting elements.

19. The photovoltaic device of claim 18 wherein said second electrode element comprises a metal selected from the group consisting of calcium (Ca), potassium (K), manganese (Mn), silver (Ag), aluminum (Al), zinc (Zn), titanium (Ti), and iron (Fe).

20. The photovoltaic device of claim 18 wherein said plurality of semiconducting carbon nanotubes are substantially all p-type carbon nanotubes.

21. The photovoltaic device of claim 18, comprising a layer of insulating material disposed between said at least one layer of semiconducting elements and said second electrode, said layer of insulating material being electrically coupled to said at least one layer of semiconducting elements and said second electrode, said layer of insulating material being positioned at said Schottky barrier.

22. The photovoltaic device of claim 21 wherein said layer of insulating material comprises a material selected from the group consisting of silicon dioxide (SiO₂), titanium dioxide (TiO₂), gallium trioxide (Ga₂O₃), tantalum pentoxide (Ta₂O₅), aluminum oxide (Al₂O₃), and diamond.

23. The photovoltaic device of claim 21 wherein said layer of insulating material is formed through one of a sputter deposition process, a chemical vapor deposition (CVD) process, and an atomic layer deposition (ALD) process.

24. The photovoltaic device of claim 21 wherein said layer of insulating material is comprised of a plurality of nonconductive nanotubes.

25. The photovoltaic device of claim 21 wherein said layer of insulating material is comprised of a plurality of nanotube elements coated with a plurality of nonconductive nanoparticles.

26. A photovoltaic power generating system comprising:
multiple photovoltaic devices electrically coupled together; and
an electrical inverter electrically coupled to an output section of said multiple photovoltaic devices,
wherein said inverter receives a DC electric current from said output section and converts the DC electric current to an AC electric current,
wherein each of said multiple photovoltaic devices comprises
a first electrode element,
a second electrode element,
at least one layer of semiconducting elements disposed between said first and second electrode elements, said at least one layer of semiconducting elements comprising a fabric of semiconducting carbon nanotubes having a first conductivity type, said at least one layer of semiconducting elements having a first side and a second side, and
at least one charge-separating junction formed at said at least one layer of semiconducting elements,
wherein said first side of said at least one layer of semiconducting elements is electrically coupled to said first electrode element, and
wherein said second side of said at least one layer of semiconducting elements is electrically coupled to said second electrode element.

27. The photovoltaic power generating system of claim 26 wherein said at least one layer of semiconducting elements further comprises a plurality of semiconducting nanostructures, and wherein said at least one charge-separating junction is a p-n junction formed between said carbon nanotubes and said semiconducting nanostructures.

28. The photovoltaic power generating system of claim 26 wherein said at least one charge-separating junction is a Schottky barrier formed at an interface between the second electrode and said at least one layer of semiconducting elements.

29. A method of fabricating photovoltaic device, comprising:
forming at least one layer of semiconducting elements on a first electrode element, said at least one layer of semiconducting elements comprising a plurality of carbon nanotubes of a first conductivity type, said at least one layer of semiconducting elements having a first side and a second side, said first side of the layer of semiconducting elements disposed at a surface of said first electrode element, said first side of said at least one layer of semiconducting elements being electrically coupled to said first electrode element;
forming a second electrode element at said second side of said at least one layer of semiconducting elements, said second side of said at least one layer of semiconducting elements being electrically coupled to said second electrode element; and
forming at least one charge-separating junction at said at least one layer of semiconducting elements.

30. The method of claim 29 wherein said at least one layer of semiconducting elements further comprises a plurality of semiconducting nanostructures, and wherein said at least one charge-separating junction is a p-n junction formed between said carbon nanotubes and said semiconducting nanostructures.

31. The method of claim 29 wherein said at least one charge-separating junction is a Schottky barrier formed at an interface between said second electrode and said at least one layer of semiconducting elements.
